(19) United States
(12) Patent Application Publication
(10) Pub. No.: US 2018/0113546 A1
(43) Pub. Date: Apr. 26, 2018

(54) DISPLAY DEVICE AND MANUFACTURING METHOD THEREOF

(71) Applicant: Japan Display Inc., Tokyo (JP)

(72) Inventor: Takashi SASABAYASHI, Tokyo (JP)

(21) Appl. No.: 15/724,554

(22) Filed: Oct. 4, 2017

(30) Foreign Application Priority Data
Oct. 26, 2016 (JP) 2016-209191

(51) Int. Cl. G06F 3/041; H01L 27/32; H01L 51/00; G06F 3/044; G06F 3/045; G06F 3/047; G09G 3/3225

(52) U.S. Cl. CPC G06F 3/0412; H01L 27/323; H01L 27/3276; H01L 51/0097; G06F 3/044; G06F 2203/04102; G06F 3/047; G09G 3/3225; H01L 2251/5338; G06F 2203/04103; G06F 3/045

(57) ABSTRACT

Disclosed is a display device including a substrate, a pixel over the substrate, and a wiring overlapping with the pixel and having a zig-zag region between terminals thereof. The display device may further possess a circuit including first to third resistors each having a first terminal and a second terminal. In this circuit, the terminals of the wiring are electrically connected to the first terminal of the first resistor and the first terminal of the third resistor, respectively, and the first terminal and the second terminal of the second resistor are electrically connected to the second terminal of the first resistor and the second terminal of the third resistor, respectively.

### CROSS REFERENCE TO RELATED APPLICATIONS

This application is based on and claims the benefit of priority from the prior Japanese Patent Application No. 2016-209191, filed on Oct. 26, 2016, the entire contents of which are incorporated herein by reference.

### FIELD

An embodiment of the present invention relates to a flexible display device. For example, an embodiment of the present invention relates to a display device provided with flexibility so that a three-dimensional shape thereof can be varied during use.

### BACKGROUND

An organic EL (Electroluminescence) display device having a light-emitting element in each pixel is represented as a typical example of a display device. An organic EL display device has an organic light-emitting element (hereinafter, referred to as a light-emitting element) in each of a plurality of pixels formed over a substrate. A light-emitting element possesses a layer (hereinafter, referred to as an organic layer or an EL layer) including an organic compound between a pair of electrodes and is operated by supplying current between the pair of electrodes.

A light-emitting element is fabricated as an all-solid display device. Hence, even if flexibility is provided to a substrate and a display device is folded or bent, display quality is not influenced in principle because, unlike a liquid crystal element, a change of a gap between substrates does not cause any influence on display quality. This characteristic has been utilized to manufacture a so-called flexible display (sheet display) in which light-emitting elements are fabricated over a flexible substrate. For example, Japanese patent application publication No. 2003-15795 discloses a flexible housing and a flexible organic EL display device supported by the housing. In this display device, operation by a user is sensed by using a pressure sensor installed in the housing.

### SUMMARY

An embodiment of the present invention is a display device including a substrate, a pixel over the substrate, and a wiring overlapping with the pixel and having a zig-zag shape between terminals thereof.

An embodiment of the present invention is a display device including a substrate, a pixel over the substrate, and first to nth wirings each overlapping with the pixel and having a zig-zag shape between terminals thereof. n is a natural number larger than 1.

An embodiment of the present invention is a method for estimating a three-dimensional shape of a display device. The method includes: estimating a change in resistance of a wiring arranged over a pixel of the display device when the display device is deformed; and calculating a curvature of the display device on the basis of the change in resistance. The wiring has a region with a zig-zag shape between terminals thereof.

### BRIEF DESCRIPTION OF DRAWINGS

FIG. 1 is a developed view showing a structure of a display device according to an embodiment of the present invention;

FIG. 2 is a schematic top view of a display device according to an embodiment of the present invention;

FIG. 3 is a schematic top view of a display device according to an embodiment of the present invention;

FIG. 4 shows a detecting wiring and a configuration of a circuit connected to the detecting wiring of a display device according to an embodiment of the present invention;

FIG. 5 is a schematic top view of a display device according to an embodiment of the present invention;

FIG. 6A and FIG. 6B are schematic top views of a display device according to an embodiment of the present invention;

FIG. 7 is a schematic cross-sectional view of a display device according to an embodiment of the present invention;

FIG. 8 is a schematic cross-sectional view of a display device according to an embodiment of the present invention;

FIG. 9 is a schematic cross-sectional view of a display device according to an embodiment of the present invention;

FIG. 10 is a schematic cross-sectional view of a display device according to an embodiment of the present invention;

FIG. 11 is a schematic cross-sectional view of a display device according to an embodiment of the present invention;

FIG. 12 is a schematic cross-sectional view of a display device according to an embodiment of the present invention;

FIG. 13 is a layout view of a detecting wiring of a display device according to an embodiment of the present invention;

FIG. 14 is a layout view of a detecting wiring of a display device according to an embodiment of the present invention;

FIG. 15A to FIG. 15C are schematic cross-sectional views for explaining a manufacturing method of a display device according to an embodiment of the present invention;

FIG. 16A to FIG. 16C are schematic cross-sectional views for explaining a manufacturing method of a display device according to an embodiment of the present invention;

FIG. 17A to FIG. 17C are schematic cross-sectional views for explaining a manufacturing method of a display device according to an embodiment of the present invention;

FIG. 18A and FIG. 18B are schematic cross-sectional views for explaining a manufacturing method of a display device according to an embodiment of the present invention;

FIG. 19 is a schematic cross-sectional view for explaining a manufacturing method of a display device according to an embodiment of the present invention; and

FIG. 20 is a schematic cross-sectional view for explaining a manufacturing method of a display device according to an embodiment of the present invention.

### DESCRIPTION OF EMBODIMENTS

Hereinafter, the embodiments of the present invention are explained with reference to the drawings. The invention can be implemented in a variety of different modes within its concept and should not be interpreted only within the disclosure of the embodiments exemplified below.

The drawings may be illustrated so that the width, thickness, shape, and the like are illustrated more schematically compared with those of the actual modes in order to provide a clearer explanation. However, they are only an example, and do not limit the interpretation of the invention. In the specification and the drawings, the same reference number is provided to an element that is the same as that which appears in preceding drawings, and a detailed explanation may be omitted as appropriate.

In the present invention, when a plurality of films is formed by processing one film, the plurality of films may have functions or rules different from each other. However, the plurality of films originates from a film formed as the same layer in the same process and has the same layer structure and the same material. Therefore, the plurality of films is defined as films existing in the same layer.

In the specification and the scope of the claims, unless specifically stated, when a state is expressed where a structure is arranged “over” another structure, such an expression includes both a case where the substrate is arranged immediately above the “other structure” so as to be in contact with the “other structure” and a case where the structure is arranged over the “other structure” with an additional structure therebetween.

### First Embodiment

### 1. Outline Structure

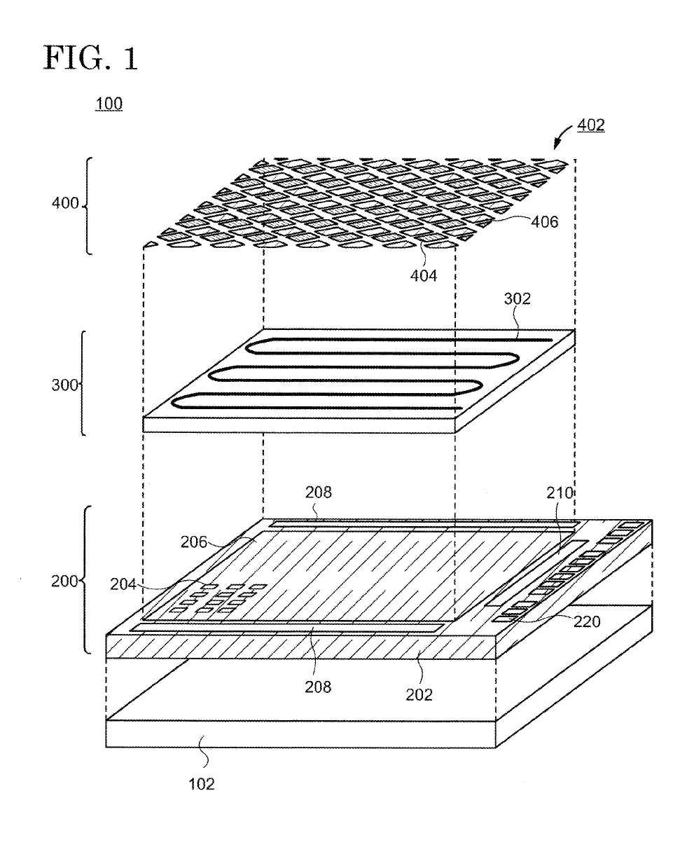

FIG. 1 is a schematic developed view of a display device 100 of the present embodiment. As shown in FIG. 1, the display device 100 has a plurality of layers which are integrated to provide the display device 100. Specifically, the display device 100 possesses a substrate 102, a display layer 200 over the substrate 102, and a strain-detecting layer (hereinafter, simply referred to as a detecting layer) 300 overlapping with the display layer 200. The display device 100 may include a touch-sensor layer 400 overlapping with the display layer 200 as an optional structure.

The display layer 200 has a function to display an image and has a plurality of pixels 204, a display region 206 in which the plurality of pixels 204 are formed, gate-line side driver circuits 208, a source-line side driver circuit 210, and the like. A display element such as a light-emitting element is provided in each of the plurality of pixels 204, and the pixels 204 are controlled with signals supplied from the gate-line side driver circuits 208 and the source-line side driver circuit 210. The pixels 204, the gate-line side driver circuits 208, and the source-line side driver circuit 210 are structured with elements such as a transistor and a capacitor, and these elements are formed in an element layer 202.

The detecting layer 300 is a layer having a function to estimate a three-dimensional shape of the display device 100. Specifically, a detecting wiring 302 which varies in resistance when deformed is disposed in the detecting layer 300, and the detecting wiring 302 overlaps with the pixels 204 and the display region 206 formed by the pixels 204. The detecting layer 300 including the detecting wiring 302 is also called a strain gauge. The aforementioned function of the detecting wiring 302 enables it to determine a three-dimensional shape of the display region 206 when the display device 100 is deformed, which permits control and adjustment of signals supplied to the pixels 204 on the basis of the three-dimensional structure. Thus, an image suitable for the three-dimensional structure of the display region 206 can be provided.

The touch-sensor layer 400 has a touch sensor 402 mounted so as to overlap with the display region 206. The touch sensor 402 may have the same size and shape as the display region 206. The touch sensor 402 possesses a plurality of first touch electrodes 404 arranged in a stripe shape in a row direction and a plurality of second touch electrodes 406 arranged in a stripe shape in a column direction and intersecting the first touch electrodes 404. One of the first touch electrode 404 and the second touch electrode 406 is called a transmitting electrode (Tx), and the other is called a receiving electrode (Rx). The first touch electrodes 404 and the second touch electrodes 406 are each spaced from one another, and capacitance is formed therebetween. When a finger of a user and the like touches the display region 206 through the first touch electrodes 404 and the second touch electrodes 406 (hereinafter, this operation is called a touch), the capacitance is changed, and sensing this change enables determination of a position of the touch. Thus, the so-called projective capacitive touch sensor 402 is fabricated by the first touch electrodes 404 and the second touch electrodes 406.

### 2. Display Layer

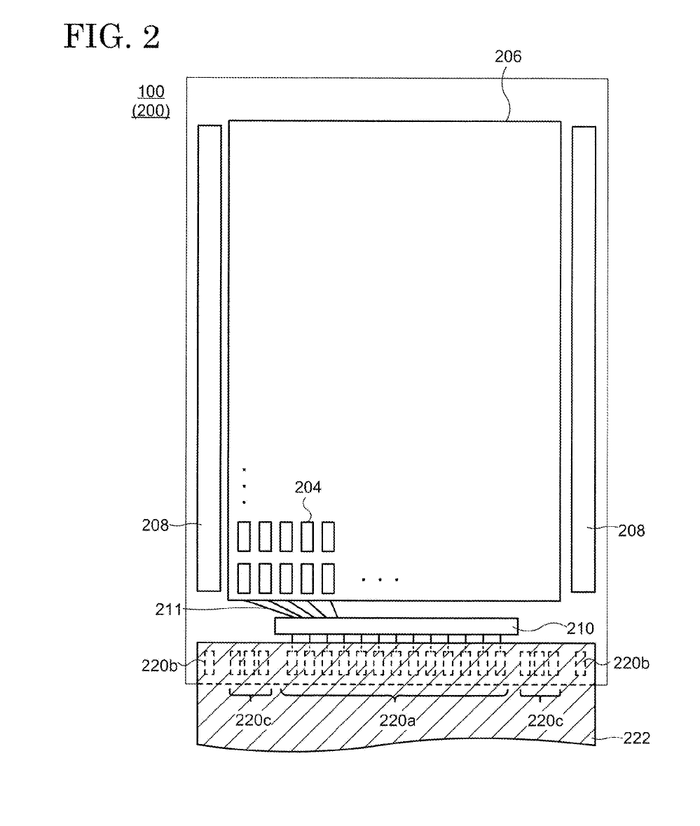

A schematic top view of the display layer 200 is shown in FIG. 2. As described above, the display layer 200 has the display region 206, and the plurality of pixels 204 are arranged in the display region 206. The gate-line side driver circuits 208 and the source-line side driver circuit 210 for controlling operation of the pixels 204 are formed outside the display region 206. These driver circuits 208 and 210 may be constructed by the elements formed in the element layer 202, or the gate-line side driver circuits 208 and the source-line side driver circuit 210 may be arranged by mounting driver circuits formed on another substrate (semiconductor substrate and the like) over the substrate 102.

As described above, a display element such as a light-emitting element is disposed in each pixel 204. Formation of red-emissive, green-emissive, and blue-emissive light-emitting elements in the respective pixels 204 enables full-color display. Alternatively, full-color display may be conducted by using white-emissive light-emitting elements in all pixels 204 and extracting red, green, and blue colors from the respective pixels 204 through a color filter. The colors eventually extracted are not limited to a combination of red, green, and blue colors, and four kinds of colors including red, green, blue, and white colors may be extracted from the pixels 204. There is also no limitation to an arrangement of the pixels 204, and a stripe arrangement, a Pentile arrangement, a mosaic arrangement, and the like may be employed.

Wirings 211 extending from the display region 206 are connected to the source-line side driver circuit 210, further extend to a side of the substrate 102, and are exposed at an edge portion of the substrate 102 to form terminals 220a. The terminals 220a are connected to a connector 222 such as a flexible printed circuit (FPC), and signals for reproducing an image are supplied from an external circuit (not shown) to the gate-line side driver circuits 208 and the source-line driver circuit 210 through the connector 222 and the terminals 220a. Note that the terminals 220a are a part of terminals 220 in FIG. 1.

### 3. Detecting Layer

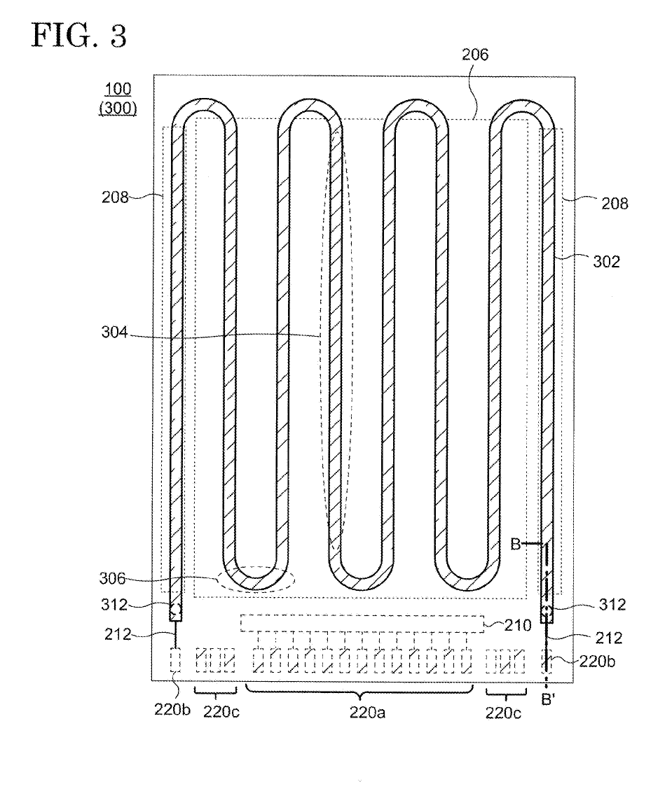

A schematic top view of the detecting layer 300 is shown in FIG. 3. As shown in FIG. 3, the detecting layer 300 possesses the detecting wiring 302. The detecting wiring 302 overlaps with the pixels 204 and at least a part of the display region 206 structured by the pixels 204. The detection wiring 302 may overlap with the gate-line side driver circuits 208 and the source-line side driver circuit 210. There is no limitation to the shape of the detecting wiring 302, and the detection wiring 302 may have a zig-zag shape as shown in FIG. 3, for example. In this example, the detecting wiring 302 has a zig-zag shape between both terminals (two end portions). This zig-zag portion includes a plurality of linear portions 304 and at least one bent portion 306. The plurality of linear portions 304 may be arranged in a stripe shape and may be disposed parallel to one another. The bent portion 306 links two linear portions 304 and physically and electrically connects them to each other. The bent portion 306 may be curved as shown in FIG. 3, or an outline thereof may be structured by straight lines. In the example of FIG. 3, a width of the detecting wiring 302 is substantially constant. However, the width may vary depending on position.

The terminals of the detecting wiring 302 are electrically connected to terminal wirings 212 formed in the display layer 200 via contact holes 312. The terminal wirings 212 are exposed at an edge portion of the display layer 200 to form terminals 220b. The terminals 220b are connected to the connector 222 shown in FIG. 2, by which the detecting wiring 302 is electrically connected to a detecting circuit 310 (described below) through the terminals 220b. Although not shown, the detecting wiring 302 may be connected to the terminals 220b via the source-line side driver circuit 210. Note that the terminals 220b are a part of the terminals 220 of FIG. 1.

The detecting wiring 302 varies in resistance when deformed. When the display device 100 is deformed by applying force from outside, the detecting wiring 302 is also deformed simultaneously. Deformation of the detecting wiring 302 internally generates stress corresponding to the applied force, which results in a change in length thereof. Strain ε expressed by the following equation is generated in the detection wiring 302 after deformation where lengths of the detecting wiring 302 before and after deformation are L and L′, respectively, and a difference (L′−L) therebetween is ΔL.

$$ɛ = \frac{Δ L}{L}$$

When the detecting wiring 302 is deformed, its resistance is also changed. The following relationship is established between the resistance and the strain, where R₁ is a resistance of the detecting wiring 302 before deformation, ΔR is a difference in resistance between before and after deformation, and Ks is a gauge factor.

$$\frac{Δ R}{{R}_{1}} = Ks \times \frac{Δ L}{L} = Ks \times ɛ$$

Therefore, measurement of the difference in resistance between before and after deformation allows estimation or determination of the three-dimensional shape of the detecting wiring 302, that is, the three-dimensional shape of the display device 100.

The detecting wiring 302 may include a metal film containing a metal such as copper, nickel, and chromium or an alloy thereof. The detecting wiring 302 may further possess a stacked structure of a transparent conductive film which can transmit visible light and a metal film. For example, a stacked structure in which a transparent conductive film is sandwiched by metal films or a stacked structure in which a metal film is sandwiched by transparent conductive films may be employed. A transparent conductive film may include a conductive oxide such as indium-tin oxide (ITO) and indium-zinc oxide (IZO).

A thickness of the detecting wiring 302 may be arbitrarily determined and may range from 100 nm to 5 μm, from 200 nm to 3 μm, or from 500 nm to 1 μm. When the display device 100 is configured so that an image is reproduced through the detecting wiring 302, the detecting wiring 302 is configured to transmit visible light. Specifically, a thickness of the metal film is adjusted to a range of 5 nm to 30 nm or 10 nm to 20 nm, for example, which permits visible light to pass therethrough.

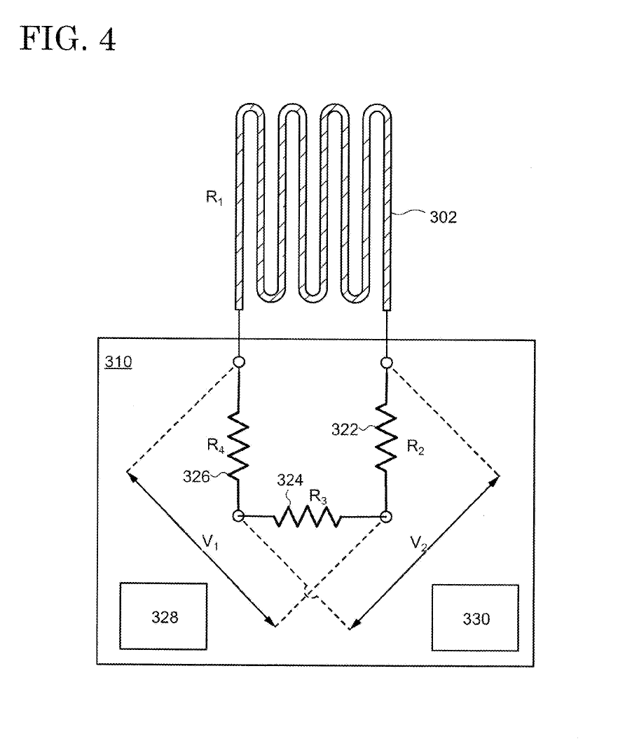

FIG. 4 shows a configuration of the detecting circuit 310 for estimating the deformation of the detecting wiring 302. The detecting circuit 310 may be installed in the external circuit connected to the display device 100 through the connector 222 or in the display device 100. For example, the detecting circuit 310 may be disposed in the source-line side driver circuit 210 or provided so as to overlap with the substrate 102. The detecting circuit 310 may include a first resistor 322, a second resistor 324, a third resistor 326, a memory 328, and a control circuit 330. The control circuit 330 controls the detecting circuit 310 in addition to the memory 328.

Both terminals of the detecting wiring 302 are electrically connected to a first terminal of the first resistor 322 and a first terminal of the third resistor 326, respectively. A first terminal and a second terminal of the second resistor 324 are electrically connected to a second terminal of the first resistor 322 and a second terminal of the third resistor 326, respectively. That is, the second resistor 324 is interposed between the second terminal of the first resistor 322 and the second terminal of the third resistor 326.

The deformation of the detecting wiring 302 is estimated in the following manner. A voltage V₂ output between the first terminal of the first resistor 322 and the second terminal of the third resistor 326 is expressed by the following equation:

$${V}_{2} = \frac{{R}_{1} {R}_{3} - {R}_{2} {R}_{4}}{( {R}_{1} + {R}_{2} ) ( {R}_{3} + {R}_{4} )} \times {V}_{1}$$

where a resistance of the detecting wiring 302 before deformation is R₁, resistances of the first resistor 322, the second resistor 324, and the third resistor 326 are R₂, R₃, and R₄, respectively, and a voltage input between the second terminal of the first resistor 322 and the first terminal of the third resistor 326 is V₁.

When the resistance R₁ of the detecting wiring 302 varies by ΔR, V₂ is represented as follows.

$${V}_{2} = \frac{( {R}_{1} + Δ R ) {R}_{3} - {R}_{2} {R}_{4}}{( {R}_{1} + + Δ R + {R}_{2} ) ( {R}_{3} + {R}_{4} )} \times {V}_{1}$$

Here, in the case of R₁=R₂=R₃=R₄, V₂ is expressed as follows.

$${V}_{2} = \frac{{R}^{2} + R Δ R - {R}^{2}}{( 2 R + Δ R ) 2 R} \times {V}_{1}$$

The above equation can be transformed as follows because it is possible to consider that R»ΔR.

$${V}_{2} \approx \frac{1}{4} \times \frac{Δ R}{R} \times {V}_{1} = \frac{1}{4} \times Ks \times ɛ \times {V}_{1}$$

Hence, the strain is expressed as follows.

$$ɛ = \frac{4 {V}_{2}}{{KsV}_{1}}$$

Hence, the strain ε can be estimated from the voltage V₁, the gauge factor of the detecting wiring 302, and the voltage V₂.

A lookup table which summarizes a relationship between the strain ε and information regarding the three-dimensional shape (e.g., curvature, bending direction, and the like) of the detecting wiring 302 may be stored in the memory 328. Alternatively, relational equations (calibration curves) demonstrating a relationship between the strain ε and the information regarding the three-dimensional shape of the detecting wiring 302 may be stored in the memory 328. The control circuit 330 refers to the lookup table or the relational equations stored in the memory 328, determines the three-dimensional shape of the detecting wiring 302 from the strain c obtained by the measurement, and transmits the information regarding the three-dimensional shape to the external circuit. The external circuit adjusts and modifies image signals on the basis of this information, and then transmits the image signals to the display device 100. With this procedure, an image synchronized with the three-dimensional shape of the display device 100 can be produced on the display region 206.

Note that, the measurement of the voltage V₂ may be carried out periodically at constant intervals, or when a user command is input. Alternatively, the measurement may be conducted when the display device 100 is started up.

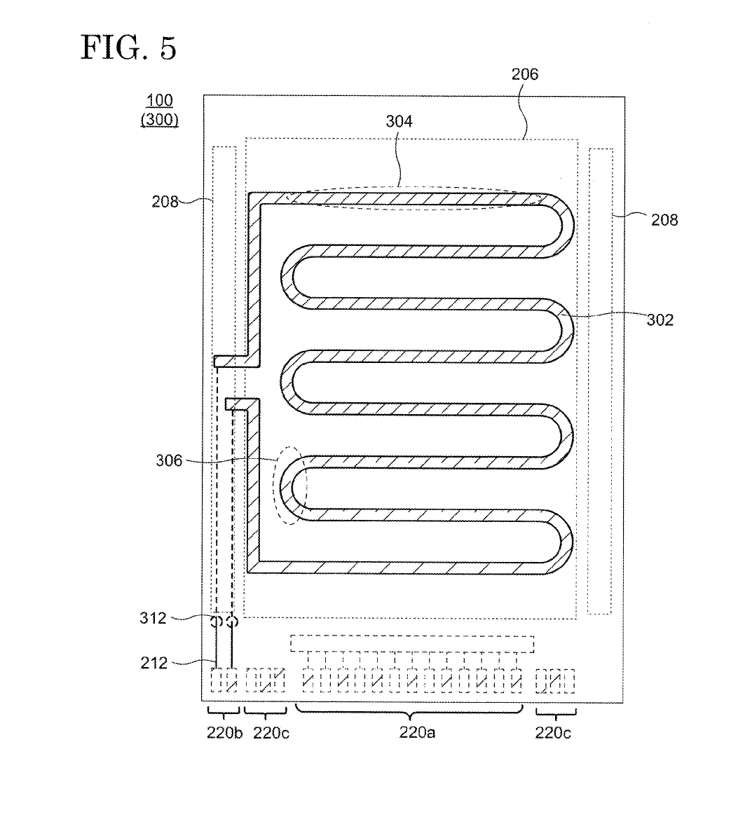

The detecting wiring 302 is disposed so that the linear portions 304 are parallel to long sides of the display device 100 in FIG. 3. Such a layout is advantageous for the display device 100 whose long sides are more readily bent or the display device 100 configured so that the long sides are more frequently bent. This is because the linear portions 304 which occupy most of the area of the detecting wiring 302 contribute to the measurement of the strain ε. The layout of the detecting wiring 302 is not limited thereto, and the detecting wiring 302 may be arranged so that the linear portions 304 are disposed parallel to the short sides of the display device 100 as shown in FIG. 5. This layout is preferred for the display device 100 whose short sides are more readily bent or the display device 100 configured so that the short sides are more frequently bent.

### 4. Touch-Sensor Layer

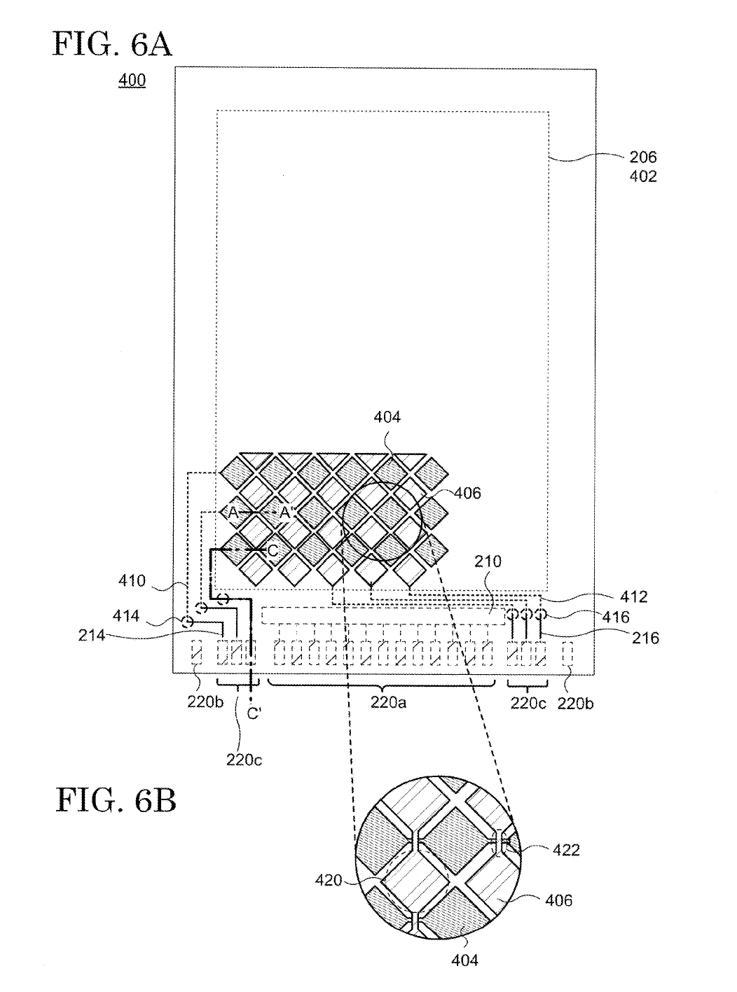

A schematic top view of the touch-sensor layer 400 is shown in FIG. 6A. As described above, the touch sensor 402 included in the touch-sensor layer 400 has the plurality of first touch electrodes 404 and the plurality of second touch electrodes 406. The first touch electrodes 404 are electrically connected to first lead wirings 410. The first lead wirings 410 extend outside the touch sensor 402 and are connected to terminal wirings 214 formed in the display layer 200 through contact holes 414. The terminal wirings 214 are partly exposed at the edge portion of the display layer 200 to form terminals 220c. The terminals 220c are connected to the connector 222, and signals for a touch sensor are provided from the external circuit to the first touch electrodes 404 via the terminals 220c. Note that the terminals 220c are also a part of the terminals 220 of FIG. 1.

Similarly, the second touch electrodes 406 are electrically connected to second lead wirings 412. The second lead wirings 412 extend outside the touch sensor 402 and are connected to terminal wirings 216 formed in the display layer 200 through contact holes 416. The terminal wirings 216 are partly exposed at the edge portion of the display layer 200 to form the terminals 220c. The terminals 220c are connected to the connector 222, and the signals for a touch sensor are provided from the external circuit to the second touch electrodes 404 via the terminals 220c. Preparation of the terminals 200a, 220b, and 220c for providing the signals to the display region 206, the detecting wiring 302, and the touch sensor 402 in or over the display layer 200 enables it to supply the aforementioned signals to the display device 100 by using the single connector 222, by which a manufacturing process of the display device 100 can be simplified and manufacturing costs thereof can be reduced.

An expanded aspect of a part of FIG. 6A is shown in FIG. 6B. As shown in FIG. 6B, the first touch electrodes 404 and the second touch electrodes 406 each have a plurality of square regions (diamond electrode) 402 having a substantially square shape and a plurality of connection portions 422, and the square region 420 and the connection portion 422 alternate with each other.

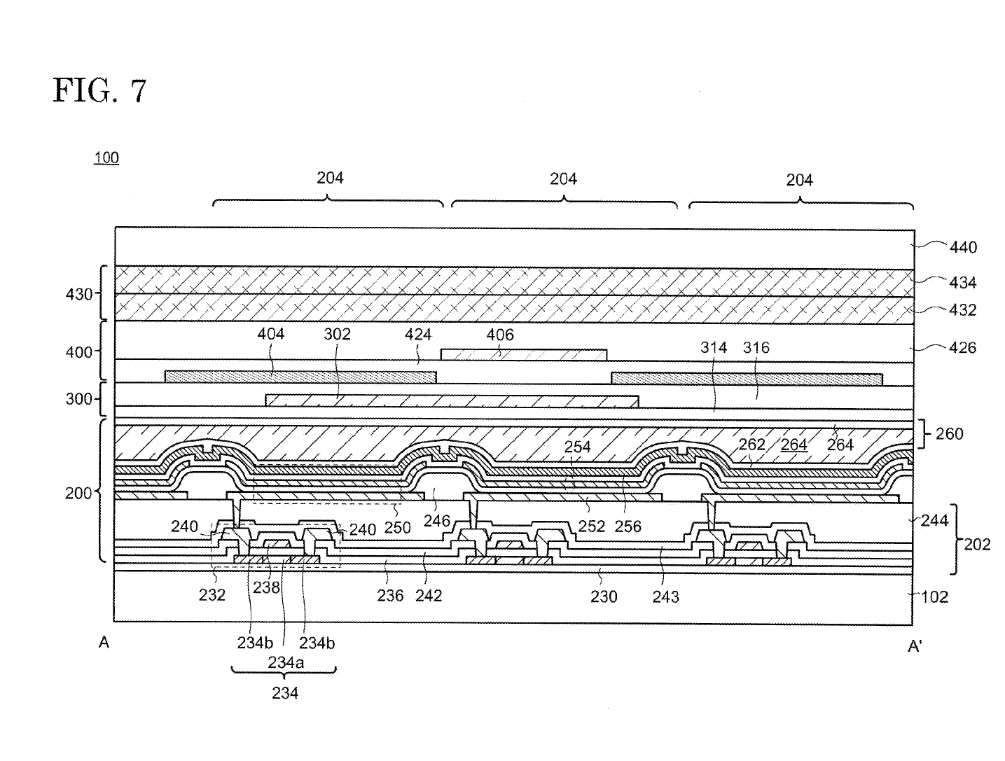

The first touch electrodes 404 and the second touch electrodes 406 may be formed in the same layer or different layers. An example is shown in FIG. 6B where the first touch electrodes 404 and the second touch electrodes 406 are disposed in different layers with an insulating film (interlayer insulating film 424. See FIG. 7) interposed therebetween. The connection portion 422 between the adjacent diamond electrodes 420 of the second touch electrode 406 overlaps with the connection portion 422 between the adjacent diamond electrodes 420 of the first touch electrode 404.

The first touch electrodes 404 and the second touch electrodes 406 may include a conductive oxide which can transmit visible light or a metal (0-valent metal) which is unable to transmit visible light. ITO and IZO are represented as the former example, and a metal such as molybdenum, titanium, chromium, tantalum, copper, aluminum, and tungsten and an alloy thereof are exemplified as the latter example. When a metal or an alloy is employed, the first touch electrodes 404 and the second touch electrodes 406 may be formed at a thickness which permits visible light to pass therethrough. In this case, a stacked structure in which a film including a metal and a film including a conductive oxide may be used for the first touch electrodes 404 and the second touch electrodes 406. The formation of the first touch electrodes 404 and the second touch electrodes 406 so as to include a metal remarkably reduces their electric resistance and time constant. As a result, a response rate as a sensor can be improved.

### 5. Cross-Sectional Structure

A schematic cross-sectional view of the display device 100 is shown in FIG. 7. FIG. 7 is a cross section along a chain line A-A′ of FIG. 6A and schematically illustrates a cross section through the plurality of pixels 204 (here, mainly three pixels).

The display device 100 has the display layer 200, the detecting layer 300, and the touch-sensor layer 400 over the substrate 102.

### 5-1. Substrate

The substrate 102 has role to support the display layer 200, the detecting layer 300, and the touch-sensor layer 400. The substrate 102 may have flexibility, or the substrate 102 without flexibility may be used. When the substrate 102 has flexibility, the substrate 102 may be called a base material, a base film, or a sheet substrate. The substrate 102 basically has flexibility, and its material is a plastic material such as polyimide, polyethylene, and an epoxy resin.

### 5-2. Display Layer

A transistor 232 is disposed over the substrate 102 through a base film 230 which is an optional structure. The transistor 232 includes a semiconductor film 234, a gate insulating film 236, a gate electrode 238, and source/drain electrodes 240, and the like. The gate electrode 238 overlaps with the semiconductor film 234 with the gate insulating film 236 sandwiched therebetween, and a region overlapping with the gate electrode 238 is a channel region 234a of the semiconductor film 234. The semiconductor film 234 may possess source/drain regions 234b sandwiching the channel region 234a. A first interlayer film 242 may be provided over the gate electrode 238, and the source/drain electrodes 240 are electrically connected to the source/drain regions 234b in openings formed in the first interlayer film 242 and the gate insulating film 236.

The transistor 232 is illustratively shown as a top-gate type transistor in FIG. 7. However, the structure of the transistor 232 is not limited, and the transistor 232 may be a bottom-gate type transistor, a multi-gate type transistor having a plurality of gate electrodes 238, or a dual-gate type transistor in which the semiconductor film 234 is sandwiched by two gate electrodes 238 located over and under the semiconductor film 234. Furthermore, an example is shown in FIG. 7 in which one transistor 232 is provided in each of the pixels 204. However, the pixels 204 each may further possess a plurality of transistors and a capacitor.

A second interlayer film 243 covering the source/drain electrodes 240 and a leveling film 244 over the second interlayer film 243 are disposed over the transistor 232. The second interlayer film 243 has a function to prevent the entrance of impurities to the transistor 232. The leveling film 244 has a function to absorb depressions and projections caused by the transistor 232 and other semiconductor elements and provide a flat surface. In the present specification and claims, the element layer 202 in FIG. 1 means the layers from the semiconductor film 234 to the leveling film 244. Note that the second interlayer film 243 is an optional structure, and the display device 100 may be configured so that the leveling film 244 is in direct contact with the source/drain electrodes 240.

Openings are formed in the second interlayer film 243 and the leveling film 244 for electrical connection between the first electrode 252 of the light-emitting element 250 described below and the source/drain electrode 240. The light-emitting element 250 is arranged over the leveling film 244 and is structured by the first electrode (pixel electrode) 252, an organic layer 254, and a second electrode (opposing electrode) 256. A current is supplied to the light-emitting element 250 through the transistor 232. A partition wall 246 is provided to cover an edge portion of the first electrode 252. The partition wall 246 covers the edge portion of the first electrode 252, by which disconnection of the organic layer 254 and the second electrode 256 formed thereover can be prevented. The organic layer 254 is disposed to cover the first electrode 252 and the partition wall 246 over which the second electrode 256 is formed. Carriers are injected to the organic layer 254 from the first electrode 252 and the second electrode 256, and recombination of the carriers takes place in the organic layer 254. The carrier recombination leads an emissive molecule in the organic layer 254 to an excited state, and light emission is obtained through a relaxation process of the excited state to a ground state. Hence, a region in which the first electrode 252 is in contact with the organic layer 254 is an emission region in each of the pixels 204.

A structure of the organic layer 254 may be selected as appropriate and may be configured by combining a carrier-injection layer, a carrier-transporting layer, an emission layer, a carrier-blocking layer, an exciton-blocking layer, and the like, for example. An example is shown in FIG. 7 where the organic layer 254 possesses three layers 254a, 254b, and 254c. In this case, the layers 254a, 254b, and 254c may be a carrier (hole) injection/transporting layer, an emission layer, and a carrier (electron) injection/transporting layer, respectively, for example. The layer 254b serving as an emission layer may be formed for every pixel 204 and can be configured to include different materials between the pixels 204 as shown in FIG. 7. In this case, the other layers 254a and 254c may be formed to be shared by the plurality of pixels 204. An appropriate selection of materials used in the layer 254b provides emission colors different between the pixels 204. Alternatively, the structure of the layer 254b may be the same between the pixels 204. In this case, the layer 254b may be also formed to be shared by the plurality of pixels 204. Since this structure allows the same emission color to be output from the layer 254b of each pixel 204, a variety of colors (e.g., red, green, and blue colors) may be extracted from the respective pixels 204 by configuring the layer 254b to undergo white emission and using a color filter.

At least one of the first electrode 252 and the second electrode 256 of the light-emitting element 250 is configured to transmit visible light. When the second electrode 256 is configured to transmit visible light, light emission from the light-emitting element 250 is extracted through the detecting layer 300. In this case, the detecting wiring 302 is preferred to include a conductive oxide having a light-transmitting property.

A sealing film (passivation film) 260 is provided over the light-emitting element 250 as an optional structure. The passivation film 260 has a function to prevent the entrance of impurities (e.g., water, oxygen, etc.) to the light-emitting element 250 or the transistor 232 from outside. As shown in FIG. 7, the passivation film 260 may include three layers (a first layer 262, a second layer 264, and a third layer 266). An inorganic compound can be used in the first layer 262 and the third layer 266, while an organic compound can be employed in the second layer 264. The second layer 264 may be formed to absorb depressions and projections caused by the light-emitting element 250 or the partition wall 246 and to give a flat surface. Therefore, a thickness of the second layer 264 may be relatively large. In other words, it is possible to increase a distance from the first touch electrodes 404 and the second touch electrodes 406 of the touch sensor 402 to the second electrode 256 of the light-emitting element 250. Accordingly, parasitic capacitance formed between the touch sensor 402 and the second electrode 256 can be significantly decreased, and a response rate of the touch sensor 402 can be increased.

### 5-3. Detecting Layer

The detecting layer 300 is arranged over the display layer 200 and may have a first insulating film 314, the detecting wiring 302 over the first insulating film 314, and a second insulating film 316 over the detecting wiring 302. It is not always necessary to provide the first insulating film 314. In this case, the detecting wiring 302 is in contact with the passivation film 260.

The width of the detecting wiring 302 may be larger than a width and a length of the pixel 204, and the linear portions 304 may overlap with the plurality of pixels 204 in a width direction, for example.

### 5-4. Touch-Sensor Layer

The touch-sensor layer 400 includes the first touch electrodes 404 and the second touch electrodes 406. An example is shown in FIG. 7 where the first touch electrodes 404 and the second touch electrodes 406 are formed in different layers from each other and the interlayer insulating film 424 is provided between the first touch electrodes 404 and the second touch electrodes 406. Although not shown, the first touch electrodes 404 and the second touch electrodes 406 may be arranged in the same layer. In this case, at each intersection of the first touch electrode 404 and the second touch electrode 406, a connection electrode is provided to one of the first touch electrode 404 and the second touch electrode 406 so as to electrically connect the adjacent diamond electrodes 420 and cross over the other of the first touch electrode 404 and the second touch electrode 406.

The touch-sensor layer 400 may have a protection film 426 as an optional structure over the first touch electrodes 404 and the second touch electrodes 406. The protection film 426 has a function to protect the touch sensor 402 and may further function as an adhesive layer for fixing a variety of films formed thereover to the touch sensor 402.

### 5-5. Other Structures

The display device 100 may further possess a polarizing plate 430 overlapping with the display region 206 as an optional structure. The polarizing plate 430 may be a circular polarizing plate. When the polarizing plate 430 is a circular polarizing plate, the polarizing plate 430 may have a stacked structure of a ¼λ plate 432 and a linear polarizing plate 434 arranged thereover as shown in FIG. 7. When light incident on the display device 100 from outside is transformed to linearly polarized light by the linear polarizing plate 434 and then passes through the ¼λ plate 432, the light is transformed to clockwise circularly polarized light. Reflection of this circularly polarized light by the first electrode 252, the first touch electrode 404, or the second touch electrode 406 results in counterclockwise circularly polarized light which is transformed to linearly polarized light after passing through the ¼λ plate 432 again. The linearly polarized light at this time cannot pass through the linear polarizing plate 434 because the polarization plane thereof perpendicularly intersects that of the linearly polarized light before the reflection. As a result, the formation of the polarizing plate 430 suppresses reflection of outside light and allows production of a high-contrast image.

A cover film 440 may be further provided to the display device 100 as an optional structure. The cover film 440 has a function to physically protect the polarizing plate 430.

### 5-6. Connection of Detecting Wiring

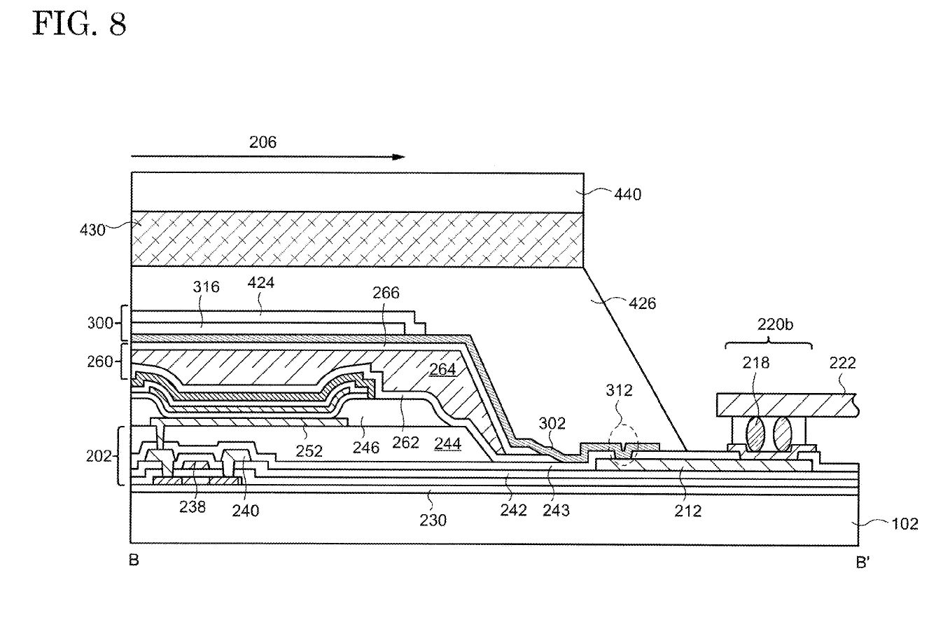

A schematic cross-sectional view along a chain line B-B′ of FIG. 3 is shown in FIG. 8. The pixel 204 located at an edge portion of the display region 206 and a connection of the detecting wiring 302 formed over the pixel 204 to the terminal 220b are schematically illustrated in FIG. 8.

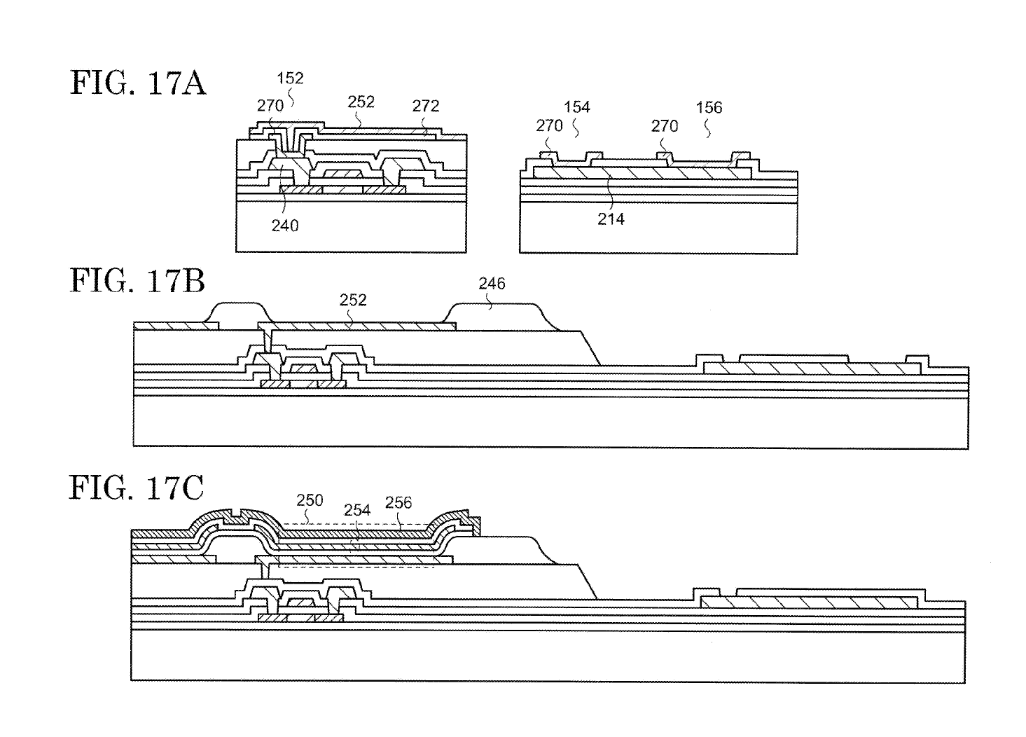

The terminal wiring 212 is disposed at a vicinity of the edge portion of the substrate 102. The terminal wiring 212 may exist in the same layer as the source/drain electrodes 240 of the transistor 232. In this case, the terminal wiring 212 is located over the first interlayer film 242, covered by the second interlayer film 243, and simultaneously formed with the source/drain electrodes 240 as shown in FIG. 8. The terminal wiring 212 may not exist in the same layer as the source/drain electrodes 240, and may be simultaneously formed with the gate electrode 238, the first electrode 252, or a connection electrode 270 described below (see FIG. 17A) so as to exist in the same layer as these electrodes, for example. Additionally, although not shown, the display device 100 may be configured so that the terminal wiring 212 is covered by the leveling film 244. In this case, the connection of the terminal wiring 212 to the detecting wiring 302 and the like is performed through openings formed in the second interlayer film 243 and the leveling film 244.

Two openings overlapping with the terminal wiring 212 are formed in the second interlayer film 243. One of the openings corresponds to the contact hole 312 used for the electrical connection between the terminal wiring 212 and the detecting wiring 302, and the other corresponds to the terminal 220b used for the electrical connection to the connector 222. The terminal wiring 212 (terminal 220b) and the connector 222 are physically and electrically connected with an adhesive 218 such as an anisotropic conductive film which is capable of exhibiting conductivity.

The passivation film 260 may be provided so as to overlap with the pixels 204, and the first layer 262 and the third layer 266 may be in contact with each other at the edge portion of the display region 206 as shown in FIG. 8. As described above, the first layer 262 and the third layer 266 may include an inorganic compound, while the second layer 264 may include an organic compound. Compared with an organic compound, an inorganic compound is generally less hydrophilic and is able to effectively block a gas such as vapor and oxygen. On the other hand, an organic compound has relatively high hydrophilicity and also serves as a transporting route of water. Thus, the second layer 264 is sealed by contacting the first layer 262 to the third layer 266 at the edge portion of the display region 206, by which entrance of water to the second layer 264 can be avoided to prevent the second layer 264 from functioning as a transporting route of water. As shown in FIG. 8, the first layer 262 may be configured so as to have a slope on its side surface and a tapered shape at its edge portion, and the third layer 266 may be formed so that the first layer 262 protrudes from the third layer 266 (that is, an edge portion of the third layer 266 overlaps with the first layer 262). With these structures, steps caused by the passivation film 260 are reduced, and it is possible to prevent the detecting wiring 302 and the first lead wiring 410 from being disconnected by the steps. Although not shown, the passivation film 260 may be configured so that an edge portion of the first layer 262 is covered by the third layer 266 or that the edge portion of the third layer 266 overlaps with the edge portion of the first layer 262.

It is preferred that the first layer 262 and the third layer 266 extend to outside the display region 106. For example, as shown in FIG. 8, the first layer 262 and the third layer 266 may extend to outside the partition wall 246 of the display region 106 and entirely cover the partition wall 246.

As shown in FIG. 8, the display device 100 may be configured so that a part of the leveling film 244 outside the display region 206 is removed to expose a part of the second interlayer film 243 and the first layer 262 makes contact with the leveling film 244 in the exposed portion. This structure allows an edge portion of the leveling film 244 to be covered by the first layer 262 and the third layer 266. That is, the leveling film 244 is arranged so as to be confined in a plane formed by the first layer 262 and the third layer 266. Furthermore, the first layer 262 passes through the leveling film 244 and makes contact with the layer located under the leveling film 244 outside the display region 106. Such a structure is also called a water-shielding structure and is able to prevent water from being transported from outside to the display region 106 through an organic compound in the leveling film 244.

The detecting layer 300 including the detecting wiring 302 is provided over the passivation film 260. Here, a structure is demonstrated where the detection layer 300 does not include the first insulating film 314 and the detecting wiring 302 is in contact with the passivation film 260. The detecting wiring 302 overlaps with the pixels 204, and a part thereof extends from the display region 206 to the edge portion of the substrate 102 and is connected to the terminal wiring 212 at the contact hole 312. With this structure, the detecting wiring 302 can be electrically connected to the external circuit including the detecting circuit 310.

The protection film 426 included in the touch-sensor layer 400 covers the detecting layer 300. In this case, the protection film 426 may be formed so as to cover the connection portion between the detecting wiring 302 and the terminal wiring 212 (that is, the contact hole 312), by which corrosion of the detecting wiring 302 outside the display region 206 can be suppressed.

### 5-7. Connection of Touch Sensor

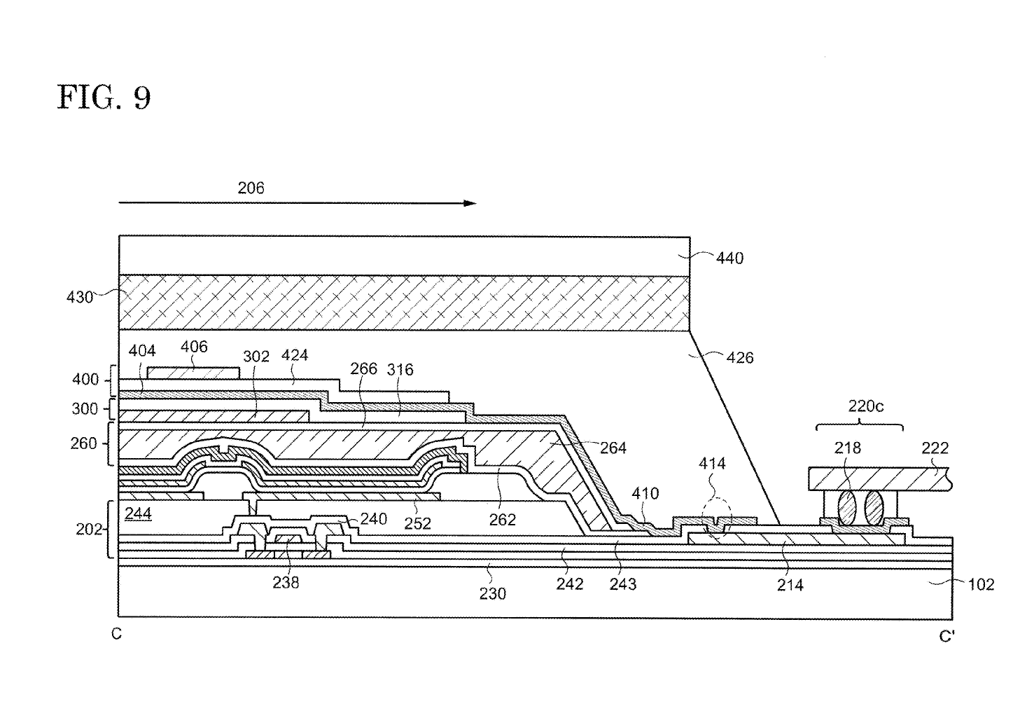

A schematic cross-sectional view along a chain line C-C′ in FIG. 6A is shown in FIG. 9. The pixel 204 located at the edge portion of the display region 206 and a connection of the touch sensor 402 formed over the pixel 204 to the terminal 220c are schematically illustrated in FIG. 9.

The terminal wiring 214 is disposed at a vicinity of the edge portion of the substrate 102. Similar to the terminal wiring 212, the terminal wiring 214 may exist in the same layer as the source/drain electrodes 240 of the transistor 232. In this case, the terminal wiring 214 is located over the first interlayer film 242, covered by the second interlayer film 243, and simultaneously formed with the source/drain electrodes 240 as shown in FIG. 9. The terminal wiring 214 may not exist in the same layer as the source/drain electrodes 240. For example, the terminal wiring 214 may be simultaneously formed with the gate electrode 238 or the first electrode 252 to exist in the same layer as these electrodes.

Two openings overlapping with the terminal wiring 214 are formed in the second interlayer film 243. One of the openings is used for the electrical connection between the terminal wiring 214 and the first touch electrode 404 of the touch sensor 402, and the other corresponds to the terminal 220c used for the electrical connection of the terminal wiring 214 to the connector 222. The terminal wiring 214 and the connector 222 are physically and electrically connected with the adhesive 218.

The touch-sensor layer 400 including the touch sensor 402 is arranged over the detecting layer 300. One of the electrodes of the touch sensor 402 (here, the first touch electrode 404) is connected to the first lead wiring 410, and the first lead wiring 410 extends to the edge portion of the substrate 102 and is connected to the terminal wiring 214 at the contact hole 414, by which the first touch electrode 404 is electrically connected to the external circuit through the connector 222. Note that the first touch electrode 404 and the first lead wiring 410 may exist in the same layer and may be integrated as shown in FIG. 9. Alternatively, the first touch electrode 404 and the first lead wiring 410 may exist in different layers. In this case, an opening is formed in the interlayer insulating film 424, and the first lead wiring 410 is formed over the interlayer insulating film 424 so as to be connected to the first touch electrode 404 through the opening.

Similar to the structure shown in FIG. 8, the protection film 426 included in the touch sensor 400 may be formed so as to cover the connection portion (that is, the contact hole 414) between the first lead wiring 410 and the terminal wiring 214, by which corrosion of the first lead wiring 410 and the like outside the display region 206 can be suppressed.

As described above, the display device 100 is provided with the detecting layer 300 for detecting strain of the display device 100, and the three-dimensional shape of the display device 100 can be determined by using the detecting wiring 302 disposed in the detecting layer 300. Image signals are adjusted and modified on the basis of the three-dimensional shape, and an image synchronized with the three-dimensional shape is reproduced on the display device 100. Therefore, even if a user deforms the display device 100 into an arbitral shape, a display suitable for the three-dimensional shape can be performed. For example, when the display region 206 is three-folded, a user cannot see an image because parts of the display region 206 overlap with each other. In this case, display may be interrupted in the overlapped region, and an entire image may be displayed by utilizing a region which can be observed by a user. Alternatively, in the case where a reproduced image is distorted when the display region 206 is bent, the image is adjusted by referring to the three-dimensional shape of the display device 100 so as to cancel the distortion. With this procedure, a user can view an image without distortion similar to the case where the image is reproduced on a flat display region.

### Second Embodiment

In the present embodiment, display devices 110, 120, and 130 having a different structure from that of the display device 100 described in the First Embodiment are explained. Explanation of the structures the same as those of the First Embodiment may be omitted.

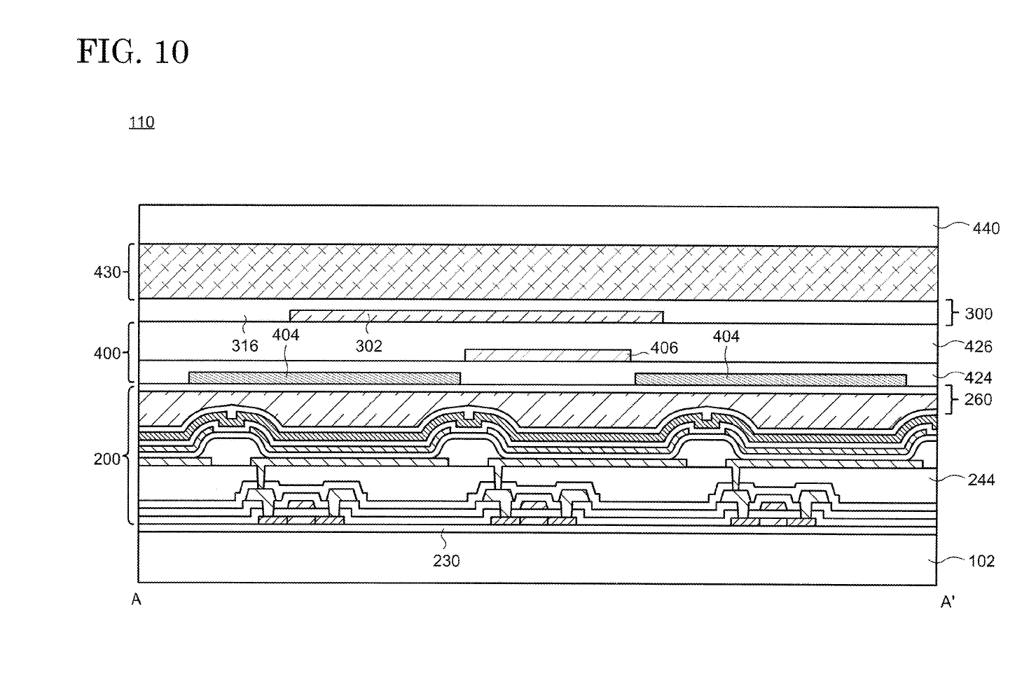

A schematic cross-sectional view of the display device 110 is shown in FIG. 10. FIG. 10 corresponds to the cross section along the chain line A-A′ of FIG. 6A. The display device 110 is different from the display device 100 in the positional relationship between the detecting layer 300 and the touch-sensor layer 400. Specifically, in the display device 110, the touch-sensor layer 400 as well as the first touch electrodes 404 and the second touch electrodes 406 included in the touch-sensor layer 400 are located over and overlap with the display layer 200 and the pixels 204 included in the display layer 200. The detecting layer 300 and the detecting wiring 302 thereof are located over and overlap with the display layer 200 and the pixels 204 included in the display layer 200 through the touch-sensor layer 400.

Similar to the display device 100, the use of such a structure enables a display suitable for the three-dimensional shape of the display region 206 even if a user deforms the display device 110 into an arbitrary shape.

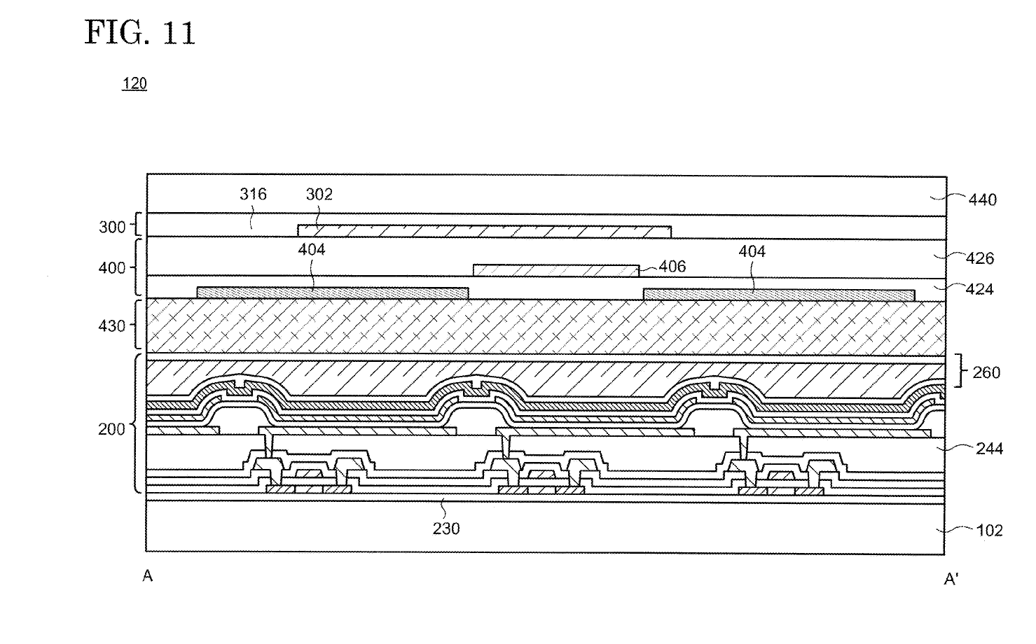

A schematic cross-sectional view of the display device 120 is shown in FIG. 11. FIG. 11 corresponds to the cross section along the chain line A-A′ of FIG. 6A. The display device 120 is different from the display device 110 in the positional relationship of the polarizing plate 430, the detecting layer 300, and the touch sensor 400. Specifically, in the display device 120, the polarizing plate 430 is formed over the display layer 200. For example, the polarizing plate 430 is disposed over the passivation film 260, and the touch-sensor layer 400 and the detecting layer 300 over the touch-sensor layer 400 are arranged over the polarizing plate 430. In this case, the cover film 440 is placed over the touch-sensor layer 400 via the detecting layer 300. Note that the detecting layer 300 may be disposed over the polarizing plate 430 over which the touch-sensor layer 400 may be arranged in the display device 120.

Similar to the display device 100, the use of such a structure enables a display suitable for the three-dimensional shape of the display region 206 even if a user deforms the display device 120 into an arbitrary shape. Additionally, it is possible to increase the distance from the first touch electrodes 404 and the second touch electrodes 406 in the touch sensor 402 to the second electrode 256 of the light-emitting element 250 in the display device 120. As a result, parasitic capacitance formed between the touch sensor 402 and the second electrode 256 can be significantly decreased, and a response rate of the touch sensor 402 can be increased.

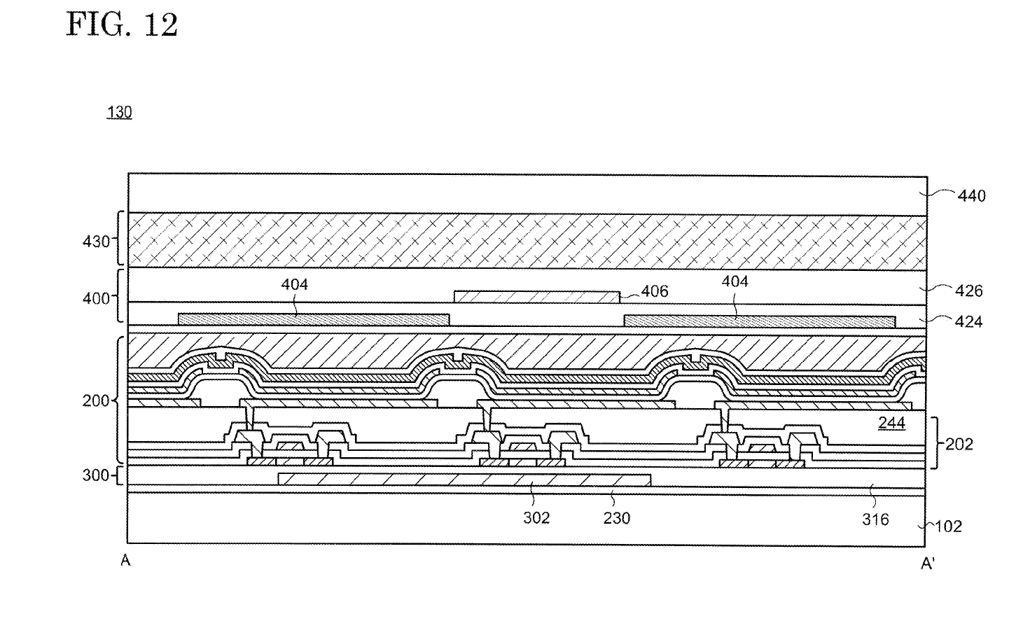

A schematic cross-sectional view of the display device 130 is shown in FIG. 12. FIG. 12 corresponds to the cross section along the chain line A-A′ of FIG. 6A. The display device 130 is different from the display device 110 in the positional relationship between the substrate 102, the display layer 200, and the detecting layer 300. Specifically, in the display device 130, the detecting layer 300 is located between the display layer 200 and the substrate 102. Although not illustrated, the detecting layer 300 may be placed under the substrate 102. In this case, the substrate 102 is located between the detecting layer 300 and the display layer 200.

Similar to the display device 100, the use of such a structure enables a display suitable for the three-dimensional shape of the display region 206 even if a user deforms the display device 130 into an arbitrary shape. Additionally, in the structure where a display produced in the display layer 200 is provided to a side opposite the substrate 102, the detecting layer 300 does not influence the display because the detecting layer 300 is located under the display layer 200. Therefore, it is not necessary to consider the light-transmitting property of the detecting layer 300. Accordingly, the display device 130 is able to display an image with higher luminance and reduce power consumption. Moreover, noise caused by the detecting wiring 302 of the detecting layer 300 is not observed in the display.

### Third Embodiment

In the present embodiment, display devices 140 and 150 having a different structure from those of the display devices described in the First and Second Embodiments are explained. Explanation of the structures the same as those of the First and Second Embodiments may be omitted.

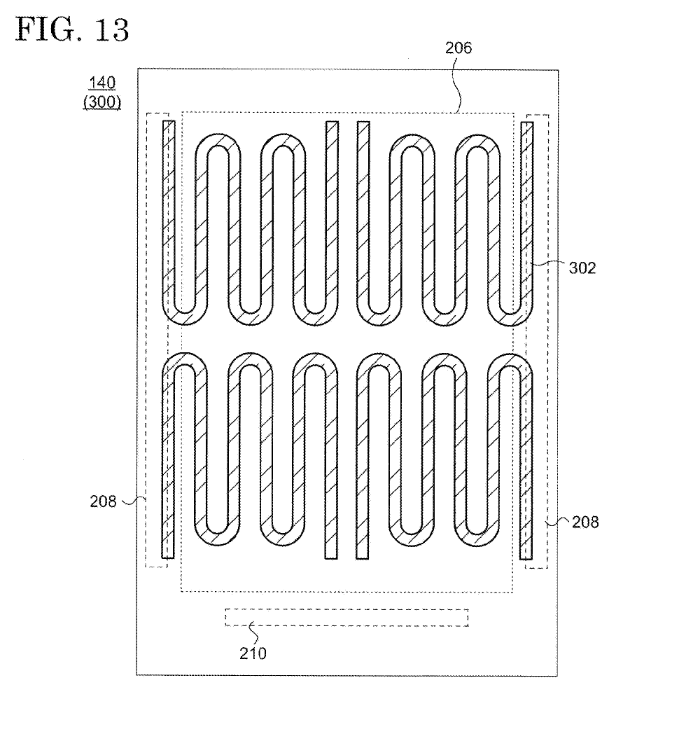

A schematic top view of the detecting layer 300 of the display device 140 according to the present embodiment is shown in FIG. 13. As shown in FIG. 13, the display device 140 is different from the display device 100 and the like in that a plurality of detecting wirings 302 is provided in the detecting layer 300. In the display device 140, four detecting wirings 302 are disposed so as to overlap with top right, top left, bottom right, and bottom left areas of the display region 206.

Formation of the plurality of detecting wirings 302 enables estimation or determination of the three-dimensional shape of each of the plurality of regions of the display device. Hence, the three-dimensional shape of the display device can be more precisely determined.

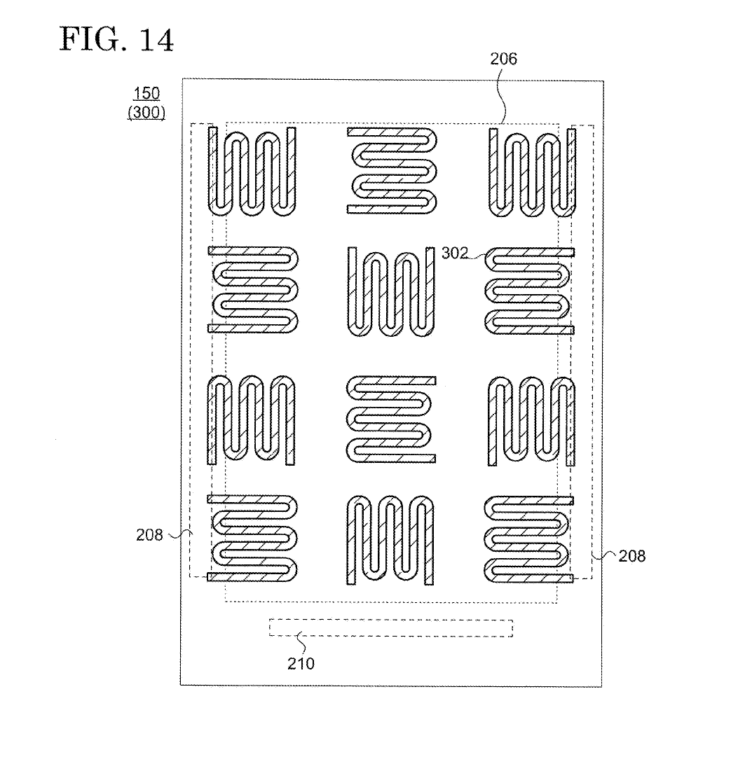

When the plurality of detecting wirings 302 is provided, the detecting wirings 302 can be arranged in a matrix form having n rows and m columns. Here, n and m are each a natural number equal to or larger than 2. For example, four detecting wirings 302 are disposed in a matrix shape having two rows and two columns in the display device 140. On the other hand, detecting wirings 302 are arranged in a matrix shape with four rows and three columns in the display device 150 shown in FIG. 14.

When the plurality of detecting wirings 302 is provided, their directions may be the same as or different from one another. For example, the direction of the linear portion 304 of the detecting wiring 302 (see FIG. 3) may be different between the plurality of detecting wirings 302 as shown in FIG. 14. In the display device 150, the direction of the linear portion 304 is different in every row and every column. Such an arrangement of the plurality of detecting wirings 302 with different directions enables detection of a strain in a variety of directions, by which the three-dimensional shape of the display device can be more precisely determined.

### Fourth Embodiment

In the present embodiment, a manufacturing method of the display device 100 shown in FIG. 9 is explained. Explanation of the structures the same as those of the First to Third Embodiments may be omitted.

### 1. Display Layer

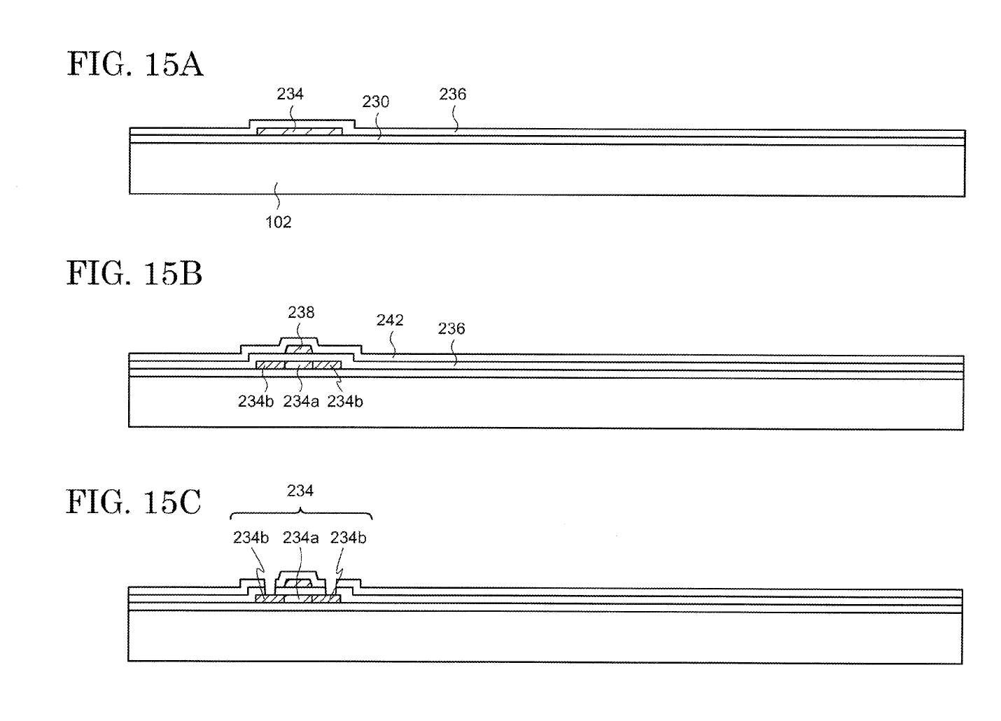

As shown in FIG. 15A, the base film 230 is first prepared over the substrate 102. The substrate 102 has a function to support the display layer 200, the detecting layer 300, and the touch-sensor layer 400. Thus, a material with heat resistance to the process temperature of a variety of elements formed thereover and chemical stability to chemicals used in the process may be used for the substrate 102. Specifically, the substrate 102 may include glass, quartz, plastics, a metal, ceramics, and the like.

When flexibility is provided to the display device 100, a base material may be formed over the substrate 102. In this case, the substrate 102 is also called a supporting substrate or a carrier substrate. The base material is an insulating film with flexibility and may include a material selected from a polymer material exemplified by a polyimide, a polyamide, a polyester, and polycarbonate. The base material may be formed by using a wet-type film-forming method such as a printing method, an ink-jet method, a spin-coating method, and a dip-coating method or a lamination method.

The base film 230 is a film having a function to prevent impurities such as an alkaline metal from diffusing to the transistor 232 and the like from the substrate 102 (and the base material) and may include an inorganic insulator such as silicon nitride, silicon oxide, silicon nitride oxide, and silicon oxynitride. The base film 230 can be formed with a chemical vapor deposition method (CVD method), a sputtering method, or the like to have a single-layer or a stacked-layer structure. When an impurity concentration of the substrate 102 is low, the base film 230 may not be formed or may be formed to only partly cover the substrate 102.

Note that, when the detecting layer 300 is fabricated between the substrate 102 and the display layer 200 as shown in FIG. 12, a layer including an organic compound or a stacked structure including a layer containing an organic compound and a layer of the aforementioned inorganic compound may be used as the base film 230. As an organic compound, a polymer material such as an epoxy resin, an acrylic resin, a polyimide, a polyamide, a polyester, a polycarbonate, and a polysiloxane is represented.

Next, the semiconductor film 234 is formed (FIG. 15A). The semiconductor film 234 may include a Group 14 element such as silicon, for example. Alternatively, the semiconductor film 234 may include an oxide semiconductor. Group 13 elements such as indium and gallium are represented as an oxide semiconductor, and a mixed oxide of indium and gallium (IGO) is exemplified. When an oxide semiconductor is used, the semiconductor film 234 may further contain a Group 12 element, and a mixed oxide including indium, gallium, and zinc (IGZO) is represented as an example. There is no limitation to crystallinity of the semiconductor film 234, and the semiconductor film 234 may include a single crystalline, a polycrystalline, a microcrystalline, or an amorphous state.

When the semiconductor film 234 includes silicon, the semiconductor film 234 may be formed with a CVD method by using a silane gas as a starting material. Crystallization may be conducted on the formed amorphous silicon by performing a heat treatment or application of light such as laser light. When an oxide semiconductor is included in the semiconductor film 234, the semiconductor film 234 can be formed with a sputtering method and the like.

Next, the gate insulating film 236 is formed to cover the semiconductor film 234 (FIG. 15A). The gate insulating film 236 may have a single-layer structure or a stacked-layer structure. The gate insulating film 236 may contain a material usable in the base film 230 and can be prepared with a method applicable to the formation of the base film 230.

Next, the gate electrode 238 is prepared over the gate insulating film 236 with a sputtering method or a CVD method (FIG. 15B). The gate electrode 238 can be formed with a metal such as titanium, aluminum, copper, molybdenum, tungsten, and tantalum or an alloy thereof to have a single-layer or a stacked layer structure. For example, a structure may be employed in which a metal with high conductivity, such as aluminum or copper, is sandwiched by a metal with a relatively high melting point, such as titanium, tungsten, or molybdenum.

After that, doping may be performed on the semiconductor film 234. For example, an ion-implantation treatment or an ion-doping treatment is carried out on the semiconductor film 234 by using the gate electrode 238 as a mask. With this process, the pair of source/drain regions 234b and the channel region 234a which is sandwiched by the source/drain regions 234b and to which an ion is not substantially added are formed (FIG. 15B).

Next, the first interlayer film 242 is formed over the gate electrode 238 (FIG. 15B). The first interlayer film 242 may have a single-layer structure or a stacked-layer structure. The first interlayer film 242 may contain a material usable in the base film 230 and can be prepared with a method applicable to the formation of the base film 230. In the case of a stacked-layer structure, a film including an inorganic compound may be stacked after forming a layer including an organic compound, for example. Note that the aforementioned doping may be conducted after forming the first interlayer film 242.

Next, etching is performed on the first interlayer film 242 and the gate insulating film 236 to form the openings reaching the semiconductor film 234 (FIG. 15C). The openings may be formed by conducting plasma etching in a gas including a fluorine-containing hydrocarbon, for example.

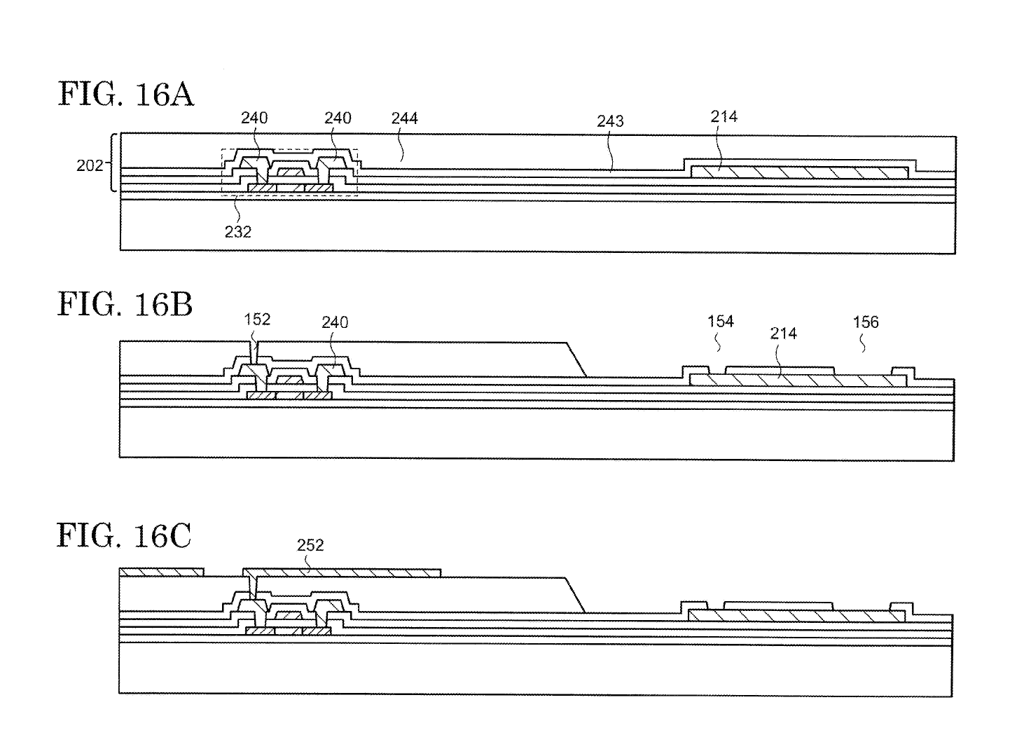

Next, a metal film is formed to cover the openings and processed with etching to form the source/drain electrodes 240 (FIG. 16A), by which the transistor 232 is fabricated.

In the present embodiment, the terminal wiring 214 is formed simultaneously with the source/drain electrodes 240. Hence, the source/drain electrodes 240 and the terminal wiring 214 can exist in the same layer. The metal film may include a material usable in the gate electrode 238, and the structure and the method applicable to the formation of the gate electrode 238 may be adopted.

Next, the second interlayer film 243 and the leveling film 244 are formed to cover the source/drain electrodes 240 and the terminal wiring 214 (FIG. 16A). The second interlayer film 243 may have a single-layer structure or a stacked-layer structure, may include a material usable in the base film 230 or the first interlayer film 242, and may be prepared with a method applicable to the formation of these films.

The leveling film 244 has a function to absorb depressions and projections caused by the transistor 232, the terminal wiring 214, and the like and to result in a flat surface. The leveling film 244 can be formed with an organic insulator. A polymer material such as an epoxy resin, an acrylic resin, a polyimide, a polyamide, a polyester, a polycarbonate, and a polysiloxane is exemplified as an organic insulator, and the leveling film 244 can be formed with a wet-type film-forming method and the like. Note that, although not shown, an insulating film including an inorganic compound such as silicon nitride, silicon nitride oxide, silicon oxynitride, and silicon oxide may be formed over the leveling film 244. Through these processes, the element layer 202 in the display layer 200 is fabricated.

Next, as shown in FIG. 16B, etching is conducted on the second interlayer film 243 and the leveling film 244 to remove a part of the leveling film 244, expose the second interlayer film 243, and form the openings 152, 154, and 156. The etching of the second interlayer film 243 and the leveling film 244 may be conducted in different processes or simultaneously. After that, the first electrode 252 is formed to cover the opening 152 (FIG. 16C).

When the light emitted from the light-emitting element 250 is extracted from the second electrode 256, the first electrode 252 is configured to reflect visible light. In this case, a metal with high reflectance, such as silver or aluminum, or an alloy thereof is used for the first electrode 252. Alternatively, a film of a conductive oxide with a light-transmitting property is formed over a film including this metal or alloy. ITO, IZO, and the like are exemplified as a conductive oxide. When the light emitted from the light-emitting element 250 is extracted from the first electrode 252, the first electrode 252 may be formed by using ITO or IZO.

In FIG. 16C, an example is demonstrated where the first electrode 252 in direct contact with the source-drain electrode 240 is formed in the opening 152. However, as shown in FIG. 17A, a structure may be employed in which the first electrode 252 is connected to the source-drain electrode 240 through the connection electrode 270. In this case, it is preferred to further prepare the connection electrode 270 in the openings 154 and 156.

The connection electrode 270 may contain a conductive oxide such as ITO and IZO, for example, and may be prepared with a sputtering method. The formation of the connection electrode 270 avoids oxidation or deterioration of the source/drain electrodes 240 and the terminal wiring 214 in the following processes and prevents an increase in contact resistance at the surfaces of these electrodes and wirings. Note that the first electrode 252 may be formed after forming an insulating film 270 including an inorganic compound such as silicon nitride, silicon nitride oxide, silicon oxynitride, and silicon oxide over the connection electrode 270 and a part of the insulating film 272 is removed in the opening 152.

Next, the partition wall 246 is prepared to cover the edge portion of the first electrode 252 (FIG. 17B). The partition wall 246 absorbs steps caused by the first electrode 252 and the like and electrically insulates the first electrodes 252 of the adjacent pixels 204. The partition wall 246 may be formed with a material usable for the leveling film 244, such as an epoxy resin and an acrylic resin, by a wet-type film-forming method.

Next, the organic layer 254 and the second electrode 256 of the light-emitting element 250 are formed to cover the first electrode 252 and the partition wall 246 (FIG. 17C). The organic layer 254 includes an organic compound and can be formed by applying a wet-type film-forming method such as an ink-jet method and a spin-coating method or a dry-type film-forming method such as an evaporation method.

When the light emitted from the light-emitting element 250 is extracted from the first electrode 252, a metal such as aluminum, magnesium, or silver or an alloy thereof may be used for the second electrode 252. On the contrary, when the light emitted from the light-emitting element 250 is extracted from the second electrode 256, a conductive oxide with a light-transmitting property, such as ITO, may be used as the second electrode 256. Alternatively, a film containing the aforementioned metal may be formed at a thickness which permits visible light to pass therethrough. In this case, a conductive oxide with a light-transmitting property may be further stacked. Through these processes, the light-emitting element 250 is fabricated.

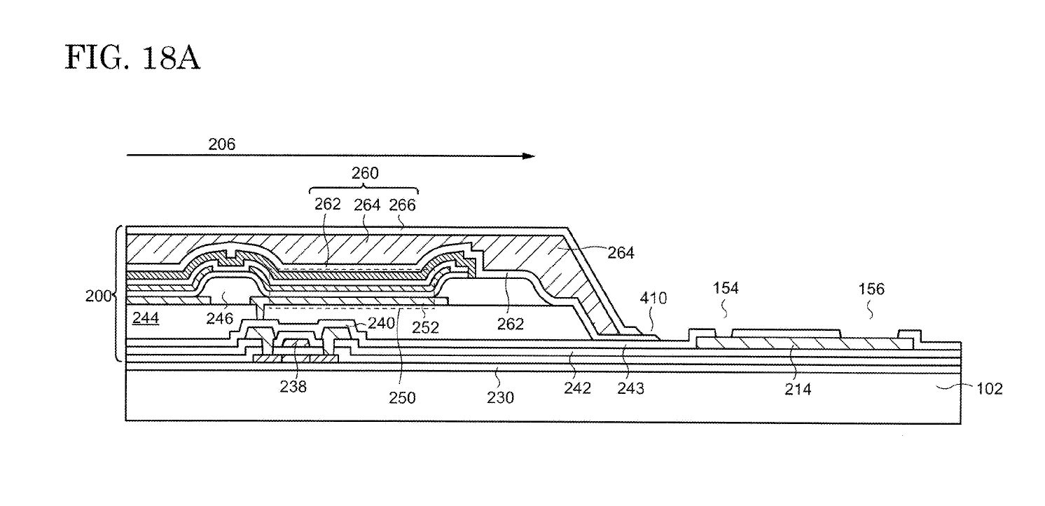

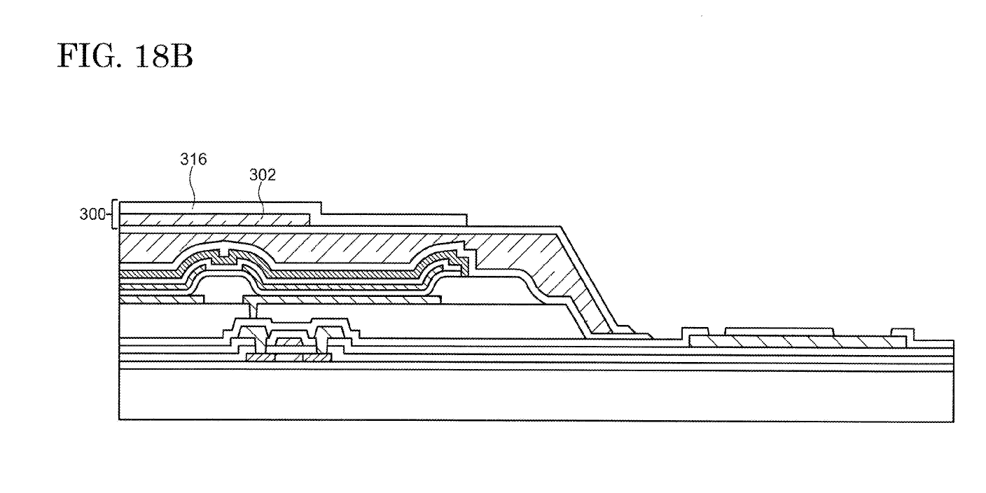

Next, the passivation film 260 is formed. As shown in FIG. 18A, the first film 262 is first formed to cover the light-emitting element 250. The first film may be formed to cover the partition wall 246 and the leveling film 244 and to be in contact with the second interlayer film 243. The first layer 262 may be also prepared so as to cover the openings 154 and 156 or the connection electrode 270 formed thereover (see FIG. 17A). The first film 262 may contain an inorganic material such as silicon nitride, silicon oxide, silicon nitride oxide, and silicon oxynitride and can be prepared with the same method as the base film 230.

Next, the second film 264 is formed (FIG. 18A). The second film 264 may contain an organic resin including an acrylic resin, a polysiloxane, a polyimide, or a polyester. Additionally, the second film 264 may be formed at a thickness which allows depressions and projections caused by the partition wall 246 to be absorbed and gives a flat surface as shown in FIG. 18A. The second film 264 is preferred to be selectively formed within the display region 206. That is, it is preferred that the second film 264 be formed so as not to cover the openings 154 and 156. When the connection electrode 270 is prepared in the openings 154 and 156, the second layer 264 is preferably formed so as not to cover the connection electrode 270. Furthermore, it is preferred that the second layer 264 be formed so as not to cover the edge portion of the first layer 262. The second layer 264 can be formed with a wet-type film-forming method such as an ink-jet method. Alternatively, the second layer 264 may be prepared by atomizing or gasifying oligomers serving as a raw material of the aforementioned polymer materials under a reduced pressure, spraying the first layer 262 with the oligomers, and then polymerizing the oligomers.

After that, the third layer 266 is formed (FIG. 18A). The third layer 266 may include a material usable in the first layer 262 and may be prepared with a method applicable to the formation of the first layer 262. The third layer 266 may be also formed to cover not only the second layer 264 but also the openings 154 and 156 or the connection electrode 270, by which the second layer 264 can be sealed by the first layer 262 and the third layer 266. As described above, the third layer 266 may be formed so that the third layer 266 covers the edge portion of the first layer 262 or the edge portion of the third layer 266 overlaps with the first layer 266 as shown in FIG. 18A. Through these processes, the display layer 200 is fabricated.

### 2. Detecting Layer

Next, the detecting wiring 302 is formed. The detecting wiring 302 may be formed with a metal such as titanium, aluminum, copper, molybdenum, tungsten, and tantalum or an alloy thereof so as to have a single-layer or stacked-layer structure. Alternatively, a film of these metals or an alloy and a film including a transparent conductive oxide such as ITO and IZO may be stacked. The latter can be formed with a sputtering method (FIG. 18B).

Alternatively, the detecting wiring 302 may be prepared by disposing a separately prepared metal foil over the passivation film 260 or the first insulating film 314 (see FIG. 7) followed by conducting etching thereon. The formation of the metal foil may be carried out by using an adhesive. In this case, the adhesive corresponds to the first insulating film 314.

When the first insulating film 314 is used, first insulating film 314 may contain an inorganic compound or an organic compound. As an inorganic compound, an inorganic insulator usable in the base film 230 can be used. As an organic compound, a material usable in the leveling film 244 or the partition wall 246 may be employed.

After forming the detecting wiring 302, the second insulating film 316 is prepared (FIG. 18B). The second insulating film 316 may include the aforementioned material usable in the first insulating film 314. Each of the first insulating film 314 and the second insulating film 316 may be formed by applying a CVD method, a sputtering method, an evaporation method, or a wet-type film-forming method. Through these processes, the detecting layer 300 is fabricated.

### 3. Touch-Sensor Layer

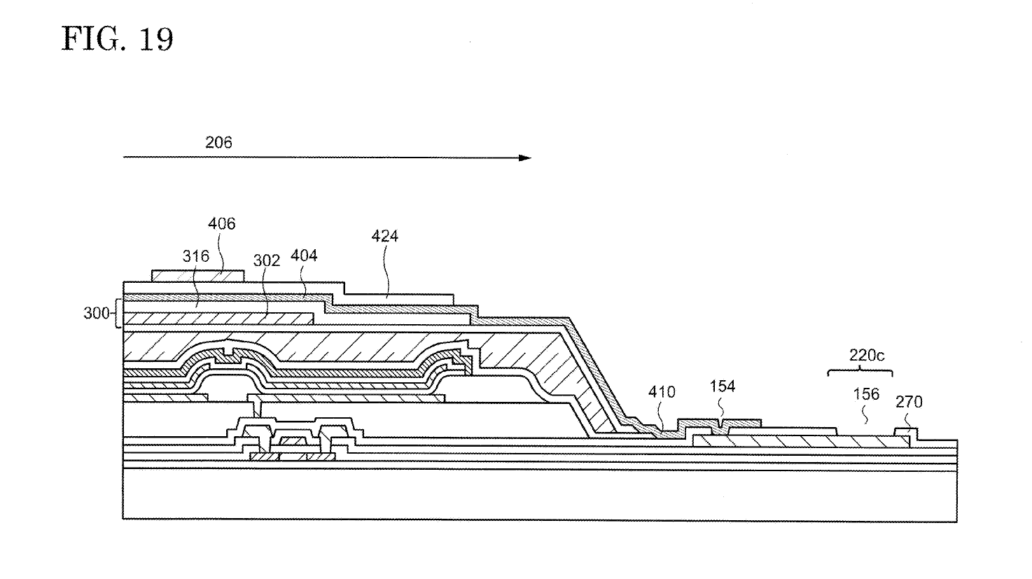

After that, the touch-sensor layer 400 is formed. Specifically, the first electrode 404 is formed over the detecting layer 300 (FIG. 19). The first touch electrode 404 may contain a transparent conductive oxide such as ITO and IZO and can be formed by using a sputtering method. When the first electrode 404 and the second electrode 406 exist in the same layer, the first electrode 404 and the second electrode 406 may be simultaneously formed.

FIG. 19 is illustrated so that the first electrode 404 extends from the display region 206 to outside the display region 206 and a part thereof functions as the first lead wiring 410. However, the present embodiment is not limited thereto, and the first touch electrode 404 and the first lead wiring 410 may be formed in different steps. In such a case, the first lead wiring 410 may be prepared with a CVD method or a sputtering method by using a metal such as titanium, molybdenum, aluminum, and copper or an alloy thereof.

The first lead wiring 410 is formed so as to cover the opening 154, by which the first touch electrode 404 is electrically connected to the terminal wiring 214 through the first lead wiring 410.

Next, the interlayer insulating film 424 is formed over the first touch electrode 404 (FIG. 19). The interlayer insulating film 424 may include a material usable in the base film 230 and the leveling film 244 and may be prepared with a method applicable to the formation of these films.

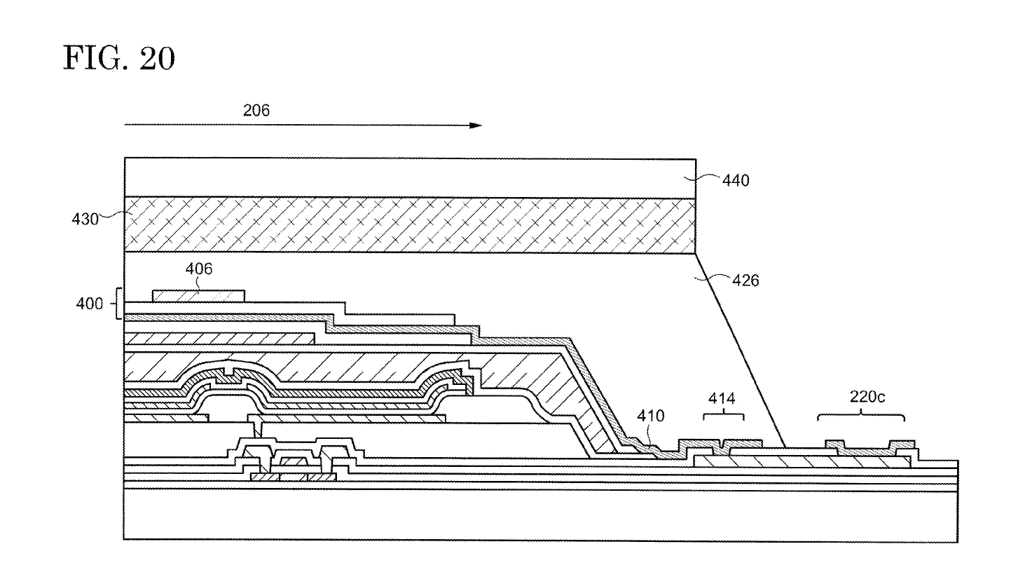

After that, the protection film 426 is prepared over the second touch electrode 406 (FIG. 20). The protection film 426 is formed so as to cover the first lead wiring 410 and the opening 154 (that is, the contact hole 414) as well as the second touch electrode 406. The protection film 426 may include a polymer material such as a polyester, an epoxy resin, and an acrylic resin and may be formed by applying a printing method, and a lamination method, and the like. Through these processes, the touch-sensor layer 400 is fabricated.

### 4. Other Layers

After that, the polarizing plate 430 and the cover film 440 are formed as an optional structure (FIG. 20). Similar to the protection film 426, the cover film 440 may also contain a polymer material, and it is possible to apply a polymer material such as a polyolefin and a polyimide in addition to the aforementioned polymer material.

Next, the connector 222 is connected at the terminal 220c with the adhesive 218, by which the display device 100 shown in FIG. 9 is fabricated.

Although not shown, when flexibility is provided to the display device 100, light such as a laser may be applied on a side of the substrate 102 to reduce adhesion between the substrate 102 and the base material, and the substrate 102 may be peeled off at an interface therebetween by using physical force before connecting the connector 222, forming the polarizing plate 430, or forming the protection film 426, for example.

The aforementioned modes described as the embodiments of the present invention can be implemented by appropriately combining with each other as long as no contradiction is caused. Furthermore, any mode which is realized by persons ordinarily skilled in the art through the appropriate addition, deletion, or design change of elements or through the addition, deletion, or condition change of a process is included in the scope of the present invention as long as they possess the concept of the present invention.

In the specification, although cases of the organic EL display device are exemplified, the embodiments can be applied to any kind of display devices of the flat panel type such as other self-emission type display devices, liquid crystal display devices, and electronic paper type display device having electrophoretic elements and the like. In addition, it is apparent that the size of the display device is not limited, and the embodiment can be applied to display devices having any size from medium to large.

It is properly understood that another effect different from that provided by the modes of the aforementioned embodiments is achieved by the present invention if the effect is obvious from the description in the specification or readily conceived by persons ordinarily skilled in the art.

What is claimed is:

1. A display device comprising:
a substrate;
a pixel over the substrate; and
a wiring overlapping with the pixel and having a zig-zag region between terminals of the wiring.

2. The display device according to claim 1, further comprising a circuit including first to third resistors each having a first terminal and a second terminal,
wherein the terminals of the wiring are electrically connected to the first terminal of the first resistor and the first terminal of the third resistor, respectively, and
the first terminal and the second terminal of the second resistor are electrically connected to the second terminal of the first resistor and the second terminal of the third resistor, respectively.

3. The display device according to claim 1,
wherein the wiring is configured so as to vary in resistance when deformed.

4. The display device according to claim 1, further comprising a touch sensor which is arranged over the pixel via the wiring.

5. The display device according to claim 1, further comprising a touch sensor between the pixel and the wiring.

6. The display device according to claim 1, further comprising a touch sensor, wherein the pixel is sandwiched by the touch sensor and the wiring.

7. The display device according to claim 1,
wherein the pixel has a light-emitting element, and
the light-emitting element is configured so that light emission from the light-emitting element is extracted from a side where the wiring is provided.

8. The display device according to claim 1,
wherein the substrate is flexible.

9. A display device comprising:
a substrate;
a display region over the substrate, the display region including a plurality of pixels; and
first to nth wirings each overlapping with the display region and having a zig-zag region between terminals thereof,
wherein n is a natural number larger than 1.

10. The display device according to claim 9, further comprising a circuit including first to third resistors each having a first terminal and a second terminal,
wherein the terminals of the first wiring are electrically connected to the first terminal of the first resistor and the first terminal of the third resistor, respectively, and
the first terminal and the second terminal of the second resistor are electrically connected to the second terminal of the first resistor and the second terminal of the third resistor, respectively.

11. The display device according to claim 9,
wherein the first to nth wirings are configured so as to vary in resistance when deformed.

12. The display device according to claim 9, further comprising a touch sensor over the display region via the first to nth wirings.

13. The display device according to claim 1, further comprising a touch sensor between the plurality of pixels and the first to nth wirings.

14. The display device according to claim 9, further comprising a touch sensor, wherein the plurality of pixels is sandwiched between the touch sensor and the first to nth wirings.

15. The display device according to claim 9,
wherein the plurality of pixels each has a light-emitting element, and
the light-emitting element is configured so that light emission from the light-emitting element is extracted from a side where the first to nth wirings is provided.

16. The display device according to claim 9,
wherein the first to nth wirings each comprise:
a plurality of linear portions substantially parallel to one another; and
bent portions linking two of the plurality of linear portions, and
a direction of the linear portion of the first wiring is different from a direction of the linear portion of the nth wiring.

17. The display device according to claim 9,
wherein the substrate is flexible.

18. A method for estimating a three-dimensional shape of a display device, the method comprising:
estimating a change in resistance of a wiring arranged over a pixel of the display device when the display device is deformed; and
calculating a curvature of the display device on the basis of the change in resistance,
wherein the wiring has a zig-zag region between terminals.

19. The method according to claim 18,
wherein the change in resistance is estimated by a circuit including first to third resistors each having a first terminal and a second terminal,
the terminals of the wiring are electrically connected to the first terminal of the first resistor and the first terminal of the third resistor, respectively, and
the first terminal and the second terminal of the second resistor are electrically connected to the second terminal of the first resistor and the second terminal of the third resistor, respectively.
